(19) United States
(12) Patent Application Publication
(10) Pub. No.: US 2021/0055352 A1
(43) Pub. Date: Feb. 25, 2021

(54) DEVICE ESTIMATING CHARGE STATE OF SECONDARY BATTERY, DEVICE DETECTING ABNORMALITY OF SECONDARY BATTERY, ABNORMALITY DETECTION METHOD OF SECONDARY BATTERY, AND MANAGEMENT SYSTEM OF SECONDARY BATTERY

(71) Applicant: SEMICONDUCTOR ENERGY LABORATORY CO., LTD., Atsugi-shi, Kanagawa-ken (JP)

(72) Inventors: Kei TAKAHASHI, Isehara, Kanagawa (JP); Koji KUSUNOKI, Isehara, Kanagawa (JP); Toshiyuki ISA, Atsugi, Kanagawa (JP); Akihiro CHIDA, Isehara, Kanagawa (JP); Ryo YAMAUCHI, Atsugi, Kanagawa (JP); Kazutaka KURIKI, Ebina, Kanagawa (JP); Ryota TAJIMA, Isehara, Kanagawa (JP)

(21) Appl. No.: 16/980,598

(22) PCT Filed: Mar. 5, 2019
(86) PCT No.: PCT/IB2019/051750

§ 371 Date: Sep. 14, 2020

(30) Foreign Application Priority Data
Mar. 16, 2018 (JP) 2018-049713
Jun. 15, 2018 (JP) 2018-114814

(51) Int. Cl. G01R 31/36; G01R 31/378; G01R 31/392; G01R 31/3842; H01M 10/48; H01M 10/0525

(52) U.S. Cl. CPC G01R 31/3648; G01R 31/378; G01R 31/392; H01M 2220/20; H01M 10/48; H01M 10/0525; G01R 31/3842

(57) ABSTRACT

A control method of a secondary battery in which malfunction is less likely to occur and abnormality detection can be performed with high accuracy is provided. A charge state estimation device of a secondary battery including a device which generates electromagnetic noise, a first detection means which measures a voltage value of a secondary battery electrically connected to the device, a second detection means which measures a current value of the secondary battery electrically connected to the device, a correction means which extracts a causal relationship between electromagnetic noise and a driving pattern from data including multiple electromagnetic noise obtained using the first detection means or the second detection means, and an arithmetic means which calculates a charge rate using a regression model based on data after data correction.

### TECHNICAL FIELD

One embodiment of the present invention relates to an object, a method, or a manufacturing method. Alternatively, the present invention relates to a process, a machine, manufacture, or a composition (a composition of matter). One embodiment of the present invention relates to a semiconductor device, a display device, a light-emitting device, a secondary battery, a lighting device, or an electronic device. One embodiment of the present invention relates to an abnormality detection method of a secondary battery, and a method of charge control of a secondary battery. In particular, one embodiment of the present invention relates to an abnormality detection system of a secondary battery, a charge system of a secondary battery, and a management system of a secondary battery (also referred to as BMS “battery management system”).

Note that in this specification, a power storage device refers to every element and device having a function of storing power. For example, the power storage device includes a storage battery (also referred to as secondary battery) such as a lithium-ion secondary battery, a lithium-ion capacitor, a nickel hydrogen battery, an all-solid-state battery, and an electric double layer capacitor.

Another embodiment of the present invention relates to a neural network and a control device of a secondary battery using a neural network. One embodiment of the present invention relates to a vehicle using a neural network. One embodiment of the present invention relates to an electronic device using a neural network. One embodiment of the present invention is not limited to a vehicle, and can also be applied to a secondary battery for storing power obtained from power generation facilities such as a solar power generation panel provided in a structure body.

### BACKGROUND ART

In recent years, a variety of power storage devices such as lithium-ion secondary batteries, lithium-ion capacitors, and air batteries have been actively developed. In particular, demand for lithium-ion secondary batteries with high energy density have rapidly grown with the development of the semiconductor industry for portable information terminals such as mobile phones, smartphones, tablets, or laptop computers; game machines; portable music players; digital cameras; medical equipment; next-generation clean energy vehicles such as hybrid electric vehicles (HEVs), electric vehicles (EVs), and plug-in hybrid electric vehicles (PHEVs); electric bikes; or the like, and lithium-ion secondary batteries have become essential as rechargeable energy supply sources for the modern information society.

In addition, in an electric-powered vehicle that requires a large amount of power, a plurality of switching elements connected to a power source and the like are included; therefore, electromagnetic noise is generated when the on/off state of each switching element is switched. Electromagnetic noise refers to an electromagnetic radiation being generated through a high-frequency current being induced by a transient current due to a swathing operation. Conduction of electromagnetic noise includes conduction through a conductor and conduction through space, and the larger the power the larger the electromagnetic noise becomes. A shield can be provided to block the conduction of electromagnetic noise through space in some cases; however, the blockage thereof is difficult since there are various types of electromagnetic noise. Electromagnetic noise is strong noise for a short period of time (spike-like noise, burst-like noise, or monopulse noise). Noise generated from different sources might overlap with each other and become large electromagnetic noise in some cases. Large electromagnetic noise might cause malfunction of a circuit through the generation of electromagnetic interference (EMI) that influences the operation of other devices through a power supply line or the like.

When electromagnetic noise is input to a battery management system, the battery management system might not operate normally, or an output from a secondary battery that is not in a state of abnormality might be determined as abnormal due to the effect of electromagnetic noise.

As a battery system, Patent Document 1 in which overcharge or overdischarge, of a battery cell is examined is known.

### REFERENCE

### Patent Document

[Patent Document 1] Japanese Published Patent Application No. 2005-318751

### SUMMARY OF THE INVENTION

### Problems to be Solved by the Invention

When an output signal of an aggregate of a device including a secondary battery is monitored for a long period of time, unnecessary electromagnetic noise and an abnormal signal are mixed in the obtained observation value. An abnormal signal can be said to be a significant type of noise; however the abnormal signal can also be said to be necessary noise for safety management of a secondary battery. An object of the present invention is to disclose a device or a secondary battery control system that enables the distinction between electromagnetic noise and an abnormal signal noise of a secondary battery, performs detection of abnormality real time or semi-real time, and performs abnormality detection more accurately.

A motor, an inverter, and a DCDC converter are included in an electric-powered vehicle or the like that requires a large amount of power and large power is controlled by switching; therefore, relatively large electromagnetic noise (also referred to as switching noise) is generated and malfunction might occur due to electromagnetic noise. Another object of the present invention is to provide a control method of a secondary battery in which malfunction is less likely to occur and abnormality detection can be performed with high accuracy. In addition, the faster the operation speed of a semiconductor chip such as an LSI, the larger the change in power being consumed becomes; hence, the change in voltage increases and the change in voltage becomes noise and the noise is transferred. The number of LSIs used in a system provided in a vehicle has increased, and the increase in operation speed thereof is required to prepare for the semi-automation or automation of electric vehicles in the future. When electric vehicles are semi-automated or automated, electromagnetic noise becomes larger, hence, minimizing the effect of the electromagnetic noise and calculating a charge rate with high accuracy is set as an object of the present invention.

Another object of the present invention is a method for reducing or accurately removing electromagnetic noise, jitter or the like. Note that jitter is a variation element generated in a time-axis direction of a signal waveform and extremely short in time. When a signal is AD converted, jitter might occur in a digital signal.

### Means for Solving the Problems

A structure of the invention disclosed in this specification is a charge state estimation device of a secondary battery including a device which generates electromagnetic noise, a first detection means which measures a voltage value of a secondary battery electrically connected to the device, a second detection means which measures a current value of the secondary battery electrically connected to the device, a correction means which extracts a causal relationship between electromagnetic noise and a driving pattern from data including multiple electromagnetic noise obtained using the first detection means or the second detection means, and an arithmetic means which calculates a charge rate using a regression model based on data after data correction.

In the above structure, the regression model is a Kalman filter on the basis of a state equation.

A Kalman filter is a kind of infinite impulse response filter. A multiple regression analysis is a multivariate analysis and uses a plurality of independent variables in a regression analysis. Examples of the multiple regression analysis include a least-squares method. The regression analysis requires a large number of observation values of time series, whereas the Kalman filter has an advantage of being able to obtain an optimal correction coefficient successively as long as there is an accumulation of data to some extent. Moreover, the Kalman filter can be applied to transient time series.

As a method of estimating the internal resistance and SOC (State Of Charge) of the secondary battery, a non-linear Kalman filter (specifically an unscented Kalman filter (also referred to as UKF)) can be used. In addition, an extended Kalman filter (also referred to as EKF) can be used. Note that SOC (State Of Charge) refers to a charge state (also referred to as charge rate), and is an index in which the fully charged state is 100% and the completely discharged state is 0%.

In the above structure, data correction is performed by generating a signal with an opposite phase from the electromagnetic noise and canceling at least part of the electromagnetic noise. For example, for the generation of the signal with an opposite phase from the electromagnetic noise, power with the opposite phase is generated with a power generation means including an inverter, a converter, or the like based on a calculation result obtained by machine learning; then, the power with the opposite phase is fed back to a power source and cancelation is performed. Note that machine learning is not necessary if the data correction is not complicated; hence, cancelation can be performed by feeding back power with the opposite phase being generated by a power generation means including an inverter, a converter, or the like by an FPGA (field programmable gate array) or the like being designed as appropriate.

For an electric-powered vehicle that requires a large amount of power, correction data for forecast error is generated with a correction means, specifically by machine learning, and the correction data is linked to the driving pattern with a driving pattern and forecast error in a Kalman filter as an input, so as to cancel an effect of electromagnetic noise. Information which links the relationship between the noise and the driving pattern is embedded in the original signal. The linked correction data is applied in practical use. The causal relationship thereof is understood to some extent; therefore, the correction accuracy can be easily increased.

A driving pattern refers to a mode by which a series of operations are performed in the case where a device such as an inverter, a converter, a motor, a wireless module, or a computer is driven; for example, in an operation of an electric-powered vehicle, an accelerator being in operation which consumes power or a break being in operation where a regenerated current can be obtained can be said to be a type of a driving pattern.

By using data after correction in which unnecessary electromagnetic noise is canceled by correction using a signal with an opposite phase based on electromagnetic noise so that the effect of electromagnetic noise is canceled, a charge rate can be calculated with high accuracy based on a high-quality signal output. The signal with an opposite phase for canceling electromagnetic noise is preferably generated by machine learning.

Noise related to a micro-short circuit has a relatively high noise intensity. Therefore, for an abnormality detection of a micro-short circuit or the like, abnormality can be detected when the noise thereof exceeds a threshold value set in advance.

A micro-short circuit refers to a minute short circuit in a secondary battery and a phenomenon in which a short circuit of a positive electrode and a negative electrode of the secondary battery does not make charging and discharging impossible, and a small amount of short-circuit current flows through a minute short circuit portion. Since a large voltage change occurs even when the time thereof is relatively short and the area thereof is small, the abnormal voltage value might affect a later estimation.

A cause of a micro-short circuit is a plurality of charging and discharging; an uneven distribution of positive electrode active materials leads to local concentration of current in part of the positive electrode and the negative electrode; and then part of a separator stops functioning or a by-product is generated by a side reaction, which is thought to generate a micro short-circuit.

A thinner separator to make a secondary battery smaller and quick electric power supply at a high voltage are desired for an ideal secondary battery, both of which have configurations that allow a micro-short circuit to occur in a secondary battery easily. Although a secondary battery does not immediately become unusable because of an occurrence of a micro-short circuit, repeating charge and discharge several times might lead to abnormal heating of a secondary battery and serious accidents such as a fire due to repeated occurrence of a micro-short circuit. Therefore, the occurrence of a micro short-circuit can also be referred to as a sign of abnormality. A micro-short circuit problem occurs during charging. For example, in the case where only one battery is employed, current is controlled by a charger; thus the perceived current value does not change during a micro-short circuit, and a change in voltage is observed. However, in the case of parallel batteries, the change in voltage becomes small and sensing becomes difficult. Moreover, this change in voltage is within the range of upper and lower limit voltages of battery use, and hence a special detecting mechanism is required. Furthermore, regarding current, in parallel batteries, the internal resistance decreases when a micro-short circuit occurs; hence the amount of current that flows into a healthy battery becomes relatively small and a large amount of current flows into an abnormal battery, which is dangerous. However, it is difficult to detect an abnormality because a controlled value of current is maintained in the whole assembled battery. In the case of a structure of a typical assembled battery (also referred to as a battery pack), it is common to monitor the voltage of each set of series; however, monitoring the current of all the batteries is difficult in terms of costs and the complexity of the wirings.

By configuring an abnormality detection system, a secondary battery control system, or a secondary battery charge system for early detection of a micro-short circuit, and preventing serious accidents from happening in the case where a micro-short circuit occurs, and not using data that is the basis of the abnormality detection, in other words noise related to the micro-short circuit, for estimation after the abnormality detection, a secondary battery can be used until a micro-short circuit occurs again after the abnormality detection.

Noise related to a micro-shot circuit is not used for calculation for an estimation and the mean value of noise of the previous steps is used therein. Noise other than noise related to the micro-short circuit is corrected using a signal with an opposite phase for canceling electromagnetic noise generated by machine learning.

By distinguishing between noise related to the micro-short circuit and the other electromagnetic noise, and performing separate corrections, prediction accuracy of a parameter value of a charge rate or the like by the arithmetic means (specifically a computer) can be increased.

By performing a plurality of filtering steps collectively after performing a plurality of prediction steps collectively, instead of performing the prediction step and the filtering step successively and alternately, a gap in timing (jitter of the like) due to asynchronicity therein is corrected.

In the case of an assembled battery, a plurality of filtering steps is performed collectively after a prediction step of a plurality of batteries is performed collectively, instead of filtering each battery sequentially. Note that an assembled battery means a container (e.g., a metal can or a film exterior body) in which a plurality of secondary batteries and a predetermined circuit are contained for easy handling of secondary batteries.

When data including noise is used in a neural network, the accuracy of abnormality detection might decrease. The performance of abnormality detection tends to largely be affected by the quality of learning data. When an abnormal value such as noieis mixed in learning data, it might be determined to be abnormal even when it is normal.

Abnormal detection can be performed with high accuracy by distinguishing an abnormal value such as noise and generating correction data. Note that, in a device including at least one selected from a motor, an inverter, a converter, and a wireless module, for example, a portable information terminal, a hearing aid, an imaging device, a vacuum cleaner, an electric tool, an electric shaver, a lighting device, a toy, a medical device, a robot, a personal computer, a wearable device, not being limited to an electric vehicle, the above-mentioned problem can be solved using the present invention. In addition, in a power storage source of a building including a house and the like, the present invention can be used to solve the above-mentioned problem.

Another structure disclosed in this specification is an abnormality detection device of a secondary battery including, a voltage obtaining unit which measures a voltage value of a secondary battery; a current obtaining unit which measures a current value of a secondary battery; an arithmetic unit which calculates forecast error by calculation using a regression model with the voltage value and the current value as an input; a machine learning unit which, with the forecast error and a driving pattern as an input, generates correction data for forecast error and forms a correction model by linking the correction data and the driving pattern so as to cancel noise linked to the driving pattern; a learning result storage unit which stores a result of the machine learning unit; and a determination unit which determines whether a forecast error corrected using the correction data is normal or abnormal.

In the above structure, a Kalman filter on the basis of a state equation is used for the regression model.

In the above structure, the regression model has a feature where a plurality of filtering steps is performed successively after a plurality of prediction steps is performed successively.

In the above structure, the machine learning unit includes a neural network.

In the above structure, an abnormality notification circuit which operates and notifies a user of an abnormality only when the corrected forecast error is determined to be abnormal can be included. The abnormality notification circuit includes at least a transistor with a metal oxide layer as a channel. A transistor with a metal oxide layer as a channel has a low leakage current in an off state; hence, power consumption can be suppressed.

By learning a driving pattern and forecast error, noise and abnormality can be determined accurately to a certain extent; therefore, an abnormality detection device with high accuracy can be achieved. The problem of the synchronization gap can be solved by processing prediction steps and filtering steps collectively.

### Effect of the Invention

If electromagnetic noise can be removed in a device such as an electric-powered vehicle including a large number of semiconductor chips by the method disclosed in this specification, only the original signal element will remain, and by using the signal element for the calculation, estimation accuracy can be improved. In addition, the accuracy of abnormality detection will increase; therefore, a device or a secondary battery control system that performs abnormality detection more accurately can be achieved.

In addition, a secondary battery control method in which malfunction is less likely to occur and abnormality detection can be performed with high accuracy can be achieved by removing unnecessary electromagnetic noise.

### BRIEF DESCRIPTION OF THE DRAWINGS

FIG. 1 (A) is a block illustrating one embodiment of the present invention, and (B) is a perspective view of an assembled battery.

FIGS. 2 (A) and (B) are perspective views illustrating an example of a secondary battery and (C) is a schematic diagram illustrating a method of a current during charging.

FIGS. 3(A), (B), and (C) are diagrams each illustrating an example of a vehicle.

FIGS. 4 (A) and (B) are configuration diagrams of a management system of a secondary battery.

FIG. 5 (A) is a diagram illustrating an example of a neural network, and (B) is a diagram illustrating an LSTM.

FIG. 6 A conceptual diagram of an operation step.

FIG. 7 A flow chart.

FIG. 8 An example of a block diagram illustrating one embodiment of the present invention.

FIG. 9 An example of a flow diagram of abnormality detection illustrating one embodiment of the present invention.

FIGS. 10(A), (B), (C), and (D) are conceptual diagrams illustrating one embodiment ofthe present invention.

FIG. 11 An example of a flow chart of abnormality detection illustrating one embodiment of the present invention.

FIGS. 12 (A), (B), (C), and (D) are diagrams each illustrating an example of a device.

### MODE FOR CARRYING OUT THE INVENTION

Hereinafter, embodiments of the present invention will be described in detail using the drawings. Note that the present invention is not limited to the description below, and it is easily understood by those skilled in the art that modes and details of the present invention can be modified in various ways. In addition, the present invention should not be construed as being limited to the description in the following embodiments.

### Embodiment 1

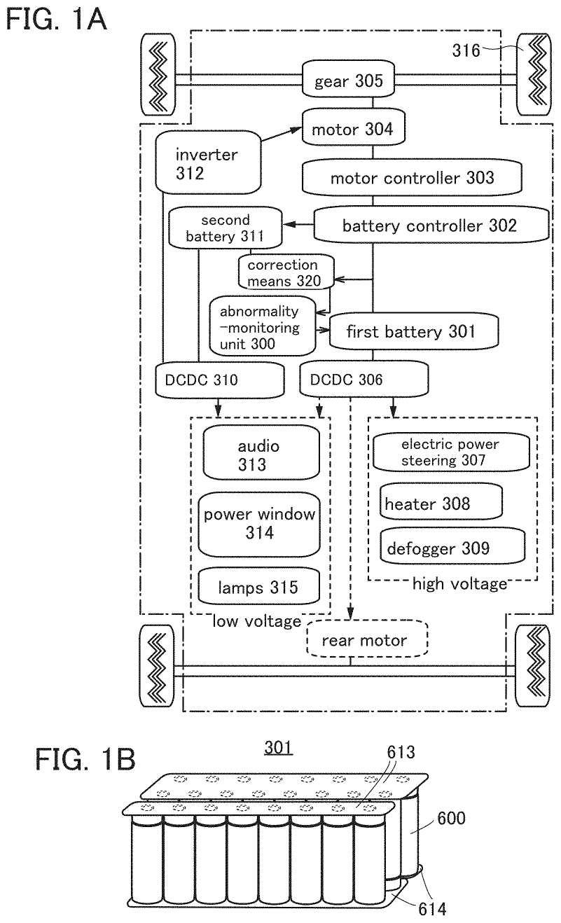

In this embodiment, an example in which the present invention is applied to an electric vehicle (EV) is described using FIG. 1(A).

In the electric vehicle, a first battery 301 as a secondary battery for main driving and a second battery 311 which supplies power to an inverter 312 starting a motor 304 are provided. In this embodiment, an abnormality-monitoring unit 300 driven by power supply from the second battery 311 monitors a plurality of secondary batteries constituting the first battery 301 collectively. A correction means 320 for generating a signal which cancels unnecessary noise from the motor 304 and the like, correcting a signal, and inputting the signal after correction into the abnormality-monitoring unit 300 is provided. The abnormality-monitoring unit 300 detects abnormality of a micro-short circuit and preforms charge state estimation by calculation. Note that the abnormality-monitoring unit 300 monitors the temperature of a temperature sensor (not illustrated) for measuring the temperature of the first battery 301. Similarly, the abnormality-monitoring unit 300 also monitors the temperature of a temperature sensor (not illustrated) for measuring the temperature of the second battery 311. An abnormality in temperature obtained in the temperature sensor can also be monitored by the abnormality-monitoring unit 300. The numeral value of the temperature sensor can be used as a parameter of calculation or machine learning explained in detail later.

An estimation method for estimating the charge state of a secondary battery is described below.

After detection of abnormality occurrence in a secondary battery is carried out, the steps for estimation continue to be repeatedly carried out. In the estimation, a means (for example, a neural network, a hidden Markov model, a polynomial function approximation, or the like) for determining an optimal output with respect to a system input by means such as regression and machine learning can be used. To perform machine learning, it is preferable to use a large amount of data and analysis for machine learning; hence the learning may be conducted at a site such as a workstation or an appliance server, and in that case one or more servers are used and data accumulation and analysis are performed automatically or semi-automatically in coordination with an operator. In the case where storage and analysis of a large amount of data have finished and results have been obtained, by integrating the results into a system, specifically a program or a memory such as an IC chip, abnormality detection and estimation of a charge state can be performed without using a server.

In a prior-estimate prediction step, an estimation algorithm and an input value are used, and in a post-estimate step (also referred to as a filtering step), an observation value is used.

x(k+1)=Ax(k)+bu(k)+bv(k) [formula 1]

The above equation is a state equation that expresses the transition of the system.

The relationship between an observation value y(k) and x(k) in a point in time (time k) is represented by the following.

y(k)=c^{T}x(k)+w(k)| [formula 2]

c^{T} is an observation model that has a function of linear mapping a state space into an observation space. w(k) represents an observation noise. The above equation is an observation equation.

The state equation and the observation equation are collectively called a state space model.

A prior-state estimation value can be expressed by the following equation.

\ddot{x}⁻(k)=A\hat{x}(k−1)+bu(k−1) [formula 3]

Note that k is 0, 1, 2, . . . , and N is discrete time. u(k) is an input signal and is a current value in the case of a secondary battery, and x(k) expresses a state variable.

In addition, prior error covariance can be expressed by the following formula.

P⁻(k)=AP(k−1)A^{T}+σ_{υ}²bb^{T} [formula 4]

In the prior estimate prediction step, the prior-state estimation value and a prior error covariance matrix of a state are calculated in accordance with the state equation. A prior state estimation value and a prior error covariance matrix at time k+1 are calculated in accordance with a post state estimation value and a post error covariance matrix of a state at time k and the state equation.

An estimation value and an actual measurement of the voltage (the observation value) are compared, and a Kalman gain which is a weight coefficient of a difference is calculated using a Kalman filter, after which the estimation value is corrected. The Kalman gain g(k) used in the filtering step can be expressed by the following equation.

$$g ( k ) = \frac{{P}^{-} ( k ) c}{{c}^{T} {P}^{-} ( k ) c + {σ}_{ω}^{2}} \qquad [ formula 5 ]$$

A post-state estimation value used in the filtering step can be expressed by the following formula.

\hat{x}(k)=\hat{x}⁻(k)+g(k)(y(k)−c^{T}\hat{x}(k)) [formula 6]

A post error covariance P(k) used in the filtering step can be expressed by the following equation.

P(k)=(I−g(k)c^{T})P⁻(k)_{υ} [formula 7]

With the above measurement model of detecting an abnormality that occur in a secondary battery, the value obtained from the equation below, that is, a difference (voltage difference) between an observation value (voltage) at a certain point in time and a voltage that is estimated using a prior-state variable is monitored, and abnormality is detected by regarding a large change in behavior of the value as an occurrence of abnormality such as a micro-short circuit.

y(k)−c^{T}\hat{x}⁻(k) [formula 8]

When the value of voltage difference obtained from the equation above exceeds a certain threshold value, a comparator or the like outputs a signal, and an abnormality is detected. An abnormality is determined by performing comparison with a voltage signal REF which is a threshold value that is input to the comparator. Data on the timing at which the abnormality is detected is not used in the estimation later, and instead, the mean value of the previous steps is input to an estimation algorithm.

When the value of voltage difference obtained from the above equation falls below a voltage signal REFL, or exceeds a voltage signal REFLH, it is replaced by the mean value of the previous steps. Therefore, when the value of voltage difference obtained from the above equation falls below the voltage signal REFL that is input to the comparator or exceeds the voltage signal REFLH, the voltage difference is not put into the Kalman filter loop. Instead, a mean value is input to the estimation algorithm, whereby estimation of SOC or the like can be performed with high accuracy even when unnecessary electromagnetic noise or an abnormality occurs. When data on the timing at which unnecessary electromagnetic noise or an abnormality of a micro-short circuit is detected is not used, and instead, the mean value of the previous steps is input to an estimation algorithm, the value of voltage difference obtained from the above equation approximates to data in the case where unnecessary electromagnetic noise or a micro-short circuit does not occur.

In the case where an unnecessary electromagnetic noise is included, the unnecessary electromagnetic noise and noise attributed to a micro-short circuit are distinguished, a signal that cancels the unnecessary electromagnetic noise is structured by machine learning, only an original signal element is left and the signal element is used for calculation to calculate a parameter value of a charge rate or the like, in the correction means 320.

The correction means 320 may generate a signal that cancels unnecessary noise, correct a signal, and perform charge state estimation by inputting the corrected signal into the abnormality-monitoring unit 300.

The order of the treatment of canceling unnecessary electromagnetic noise and the treatment of correcting a noise of a micro-short circuit is not particularly limited and whichever may be performed first. Regardless of whichever treatment is performed first, the obtained calculation result is almost the same.

The first battery 301 mainly supplies power to in-vehicle parts for 42 V (for a high-voltage system) and the second battery 311 supplies power to in-vehicle parts for 14 V (for a low-voltage system). Lead batteries are usually used for the second battery 311 due to cost advantage. Lead batteries have disadvantages compared with lithium-ion secondary batteries in that they have a larger amount of self-discharge and are more likely to degrade due to a phenomenon called sulfation. There is an advantage that the second battery 311 can be maintenance-free when it uses a lithium-ion secondary battery; however, in the case of long-term use, for example three years or more, abnormality that cannot be determined at the time of manufacturing might occur. In particular, when the second battery 311 that starts the inverter becomes inoperative, the motor cannot be started even when the first battery 301 has remaining capacity; thus, in order to prevent this, in the case where the second battery 311 is a lead storage battery, the second battery is supplied with power from the first battery to constantly maintain a fully-charged state.

In this embodiment, an example in which a lithium-ion secondary battery is used for both the first battery 301 and the second battery 311 is described. A lead battery or an all-solid-state battery can be used for the second battery 311.

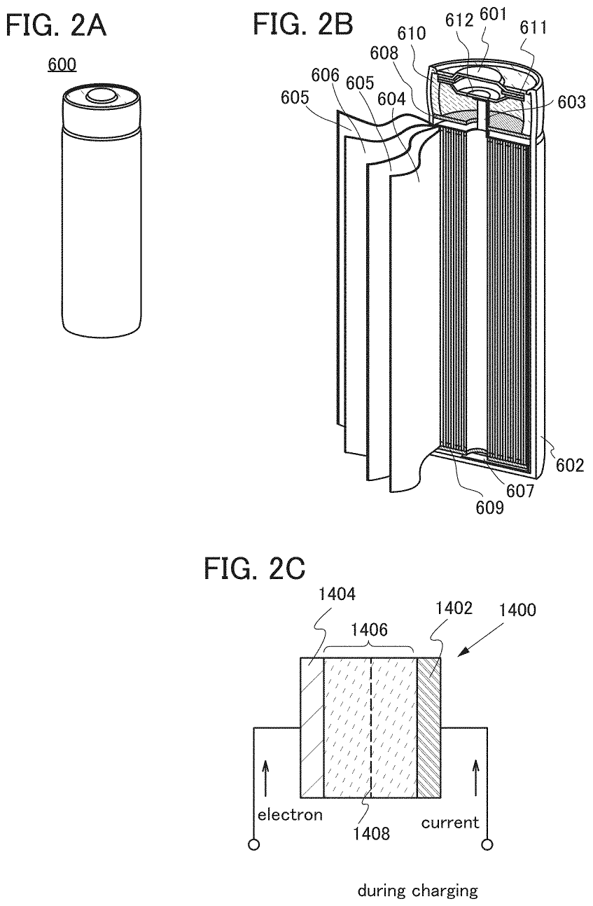

An example of a cylindrical secondary battery is described with reference to FIG. 2(A) and FIG. 2(B). A cylindrical secondary battery 600 includes, as illustrated in FIG. 2(A), a positive electrode cap (battery lid) 601 on the top surface and a battery can (outer can) 602 on the side and bottom surfaces. The positive electrode cap and the battery can (outer can) 602 are insulated by a gasket (insulating gasket) 610.

FIG. 2(B) is a diagram schematically illustrating a cross-section of a cylindrical secondary battery. Inside the battery can 602 having a hollow cylindrical shape, a battery element in which a belt-like positive electrode 604 and a belt-like negative electrode 606 are wound with a separator 605 located therebetween is provided. Although not illustrated, the battery element is wound centering around a center pin. One end of the battery can 602 is closed and the other end thereof is opened. For the battery can 602, a metal having corrosion resistance to an electrolyte solution, such as nickel, aluminum, or titanium, an alloy of such a metal, or an alloy of such a metal and another metal (e.g., stainless steel or the like) can be used. The battery can 602 is preferably covered with nickel, aluminum, or the like in order to prevent corrosion due to the electrolyte solution. Inside the battery can 602, the battery element in which the positive electrode, the negative electrode, and the separator are wound is sandwiched between a pair of insulating plates 608 and 609 that face each other. Furthermore, a nonaqueous electrolyte solution (not illustrated) is injected inside the battery can 602 provided with the battery element. The secondary battery is composed of a positive electrode containing an active material such as lithium cobalt oxide (LiCoO₂) or lithium iron phosphate (LiFePO₄), a negative electrode composed of a carbon material such as graphite capable of occluding and releasing lithium ions, a nonaqueous electrolytic solution in which an electrolyte composed of a lithium salt such as LiBF₄ or LiPF₆ is dissolved in an organic solvent such as ethylene carbonate or diethyl carbonate, and the like.

Since the positive electrode and the negative electrode of the cylindrical secondary battery are wound, active materials are preferably formed on both sides of the current collectors. A positive electrode terminal (positive electrode current collector lead) 603 is connected to the positive electrode 604, and a negative electrode terminal (negative electrode current collector lead) 607 is connected to the negative electrode 606. For both the positive electrode terminal 603 and the negative electrode terminal 607, a metal material such as aluminum can be used. The positive electrode terminal 603 and the negative electrode terminal 607 are resistance-welded to a safety valve mechanism 612 and the bottom of the battery can 602, respectively. The safety valve mechanism 612 is electrically connected to the positive electrode cap 601 through a PTC element (Positive Temperature Coefficient) 611. The safety valve mechanism 612 cuts off electrical connection between the positive electrode cap 601 and the positive electrode 604 when the internal pressure of the battery exceeds a predetermined threshold value. In addition, the PTC element 611 is a thermally sensitive resistor whose resistance increases as temperature rises, and limits the amount of current by increasing the resistance to prevent abnormal heat generation. Barium titanate (BaTiO₃)-based semiconductor ceramic or the like can be used for the PTC element.

A lithium-ion secondary battery using an electrolyte solution includes a positive electrode, a negative electrode, a separator, an electrolyte solution, and an exterior body. Note that in a lithium-ion secondary battery, the anode (positive electrode) and the cathode (negative electrode) are interchanged in charging and discharging, and the oxidation reaction and the reduction reaction are interchanged; thus, an electrode with a high reaction potential is called the positive electrode and an electrode with a low reaction potential is called the negative electrode. For this reason, in this specification, the positive electrode is referred to as a “positive electrode” or a “+ electrode (plus electrode)” and the negative electrode is referred to as a “negative electrode” or a “− electrode (minus electrode)” in any of the case where charging is performed, the case where discharging is performed, the case where a reverse pulse current is made to flow, and the case where a charge current is made to flow. The use of terms an “anode” and a “cathode” related to oxidation reaction and reduction reaction might cause confusion because the anode and the cathode interchange in charging and in discharging. Thus, the terms the “anode” and the “cathode” are not used in this specification. If the term the “anode” or the “cathode” is used, it should be clearly mentioned that the anode or the cathode is which of the one in charging or in discharging and corresponds to which of the positive electrode (plus electrode) or the negative electrode (minus electrode).

A charger is connected to two terminals shown in FIG. 2(C) to charge the secondary battery 1400. As the charging of the secondary battery 1400 proceeds, a potential difference between electrodes increases. The positive direction in FIG. 2(C) is the direction which a current flows from a terminal outside the secondary battery 1400 to a positive electrode 1402; from the positive electrode 1402 to a negative electrode 1404 in the secondary battery 1400; and from the negative electrode to a terminal outside the secondary battery 1400. In other words, the direction in which a charge current flows is regarded as the direction of a current. Note that 1406 denotes an electrolytic solution and 1408 denotes a separator.

In this embodiment, an example of a lithium-ion secondary battery is shown; however, it is not limited to a lithium-ion secondary battery and a material including an element A, an element X, and oxygen can be used as a positive electrode material for the secondary battery. The element A is preferably one or more selected from the Group 1 elements and the Group 2 elements. As a Group 1 element, for example, an alkali metal such as lithium, sodium, or potassium can be used. As a Group 2 element, for example, calcium, beryllium, magnesium, or the like can be used. As the element X, for example, one or more selected from metal elements, silicon, and phosphorus can be used. The element X is preferably one or more selected from cobalt, nickel, manganese, iron, and vanadium. Typical examples include lithium-cobalt composite oxide (LiCoO₂) and lithium iron phosphate (LiFePO₄).

The negative electrode includes a negative electrode active material layer and a negative electrode current collector. The negative electrode active material layer may contain a conductive additive and a binder.

For the negative electrode active material, an element that enables charge-discharge reaction by alloying reaction and dealloying reaction with lithium can be used. For example, a material containing at least one of silicon, tin, gallium, aluminum, germanium, lead, antimony, bismuth, silver, zinc, cadmium, indium, and the like can be used. Such elements have higher capacity than carbon. In particular, silicon has a high theoretical capacity of 4200 mAh/g.

In addition, the secondary battery preferably includes a separator. As the separator, for example, a fiber containing cellulose such as paper, nonwoven fabric; a glass fiber, ceramics; a synthetic fiber using nylon (polyamide), vinylon (polyvinyl alcohol-based fiber), polyester, acrylic, polyolefin, or polyurethane; or the like can be used.

As illustrated in FIG. 1, regenerative energy generated by rolling of tires 316 is transmitted to a motor 304 through a gear 305 and a motor controller 303 and a battery controller 302 charges the second battery 311 or the first battery 301.

The first battery 301 is mainly used for driving the motor 304 and supplies power to in-vehicle parts for 42 V (such as an electric power steering 307, a heater 308, and a defogger 309) through a DCDC circuit 306. Even in the case where there is a rear motor for the rear wheels, the first battery 301 is used to drive the rear motor.

The second battery 311 supplies power to in-vehicle parts for 14V (such as an audio 313, a power window 314, and lamps 315) through a DCDC circuit 310.

An electric-powered vehicle using the motor 304 includes a plurality of ECUs (Electronic Control Unit) and performs engine control by the ECU. The ECU includes a microcomputer. The ECU is connected to a CAN (Controller Area Network) provided in the electric-powered vehicle. The CAN is a type of a serial communication standard used as an in-vehicle LAN.

A wireless communication module using a wireless network may be provided in a vehicle to preform wireless communication.

The first battery 301 includes a plurality of secondary batteries. For example, a cylindrical secondary battery 600 illustrated in FIG. 2(A) is used. As illustrated in FIG. 1(B), the cylindrical secondary battery 600 may be interposed between a conductive plate 613 and a conductive plate 614 to form a module. In FIG. 1(B), switches are not illustrated between the secondary batteries. A plurality of secondary batteries 600 may be connected in parallel, connected in series, or connected in series after connecting in parallel. By forming a module including the plurality of secondary batteries 600, large power can be extracted.

In order to cut off electric power from the plurality of secondary batteries, the secondary batteries in the vehicle include a service plug or a circuit breaker which can cut off a high voltage without the use of equipment; these are provided in the first battery 301. For example, if 48 battery modules which each have two to ten cells are connected in series, a service plug or a circuit breaker is placed between the 24th module and the 25th module.

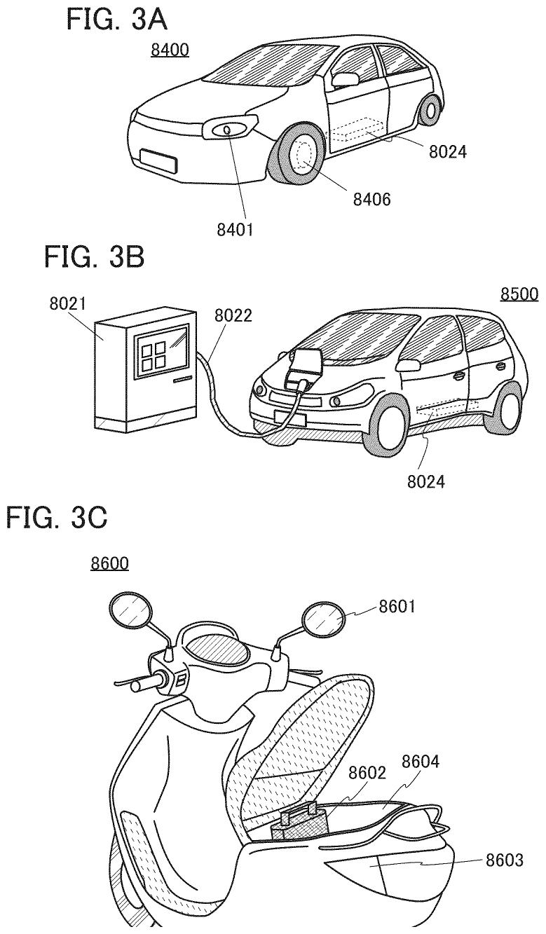

FIG. 3 illustrates examples of a vehicle using the charge state estimation device of a secondary battery of one embodiment of the present invention. A secondary battery 8024 of an automobile 8400 illustrated in FIG. 3(A) not only drives an electric motor 8406 but also can supply power to a light-emitting device such as a headlight 8401 or a room light (not illustrated). For the secondary battery 8024 in the automobile 8400, the cylindrical secondary batteries 600 illustrated in FIG. 1(B) that are interposed between the conductive plate 613 and the conductive plate 614 to form a module can be used.

An automobile 8500 illustrated in FIG. 3(B) can be charged when a secondary battery included in the automobile 8500 is supplied with power through external charging equipment by a plug-in system, a contactless power feeding system, or the like. FIG. 3(B) illustrates a state where the secondary battery 8024 incorporated in the automobile 8500 is charged from a ground installation type charging device 8021 through a cable 8022. Charging may be performed as appropriate by a given method such as CHAdeMO (registered trademark) or Combined Charging System as a charging method, the standard of a connector, or the like. The charging device 8021 may be a charging station provided in a commerce facility or a power source in a house. For example, with a plug-in technique, the secondary battery 8024 incorporated in the automobile 8500 can be charged by power supply from the outside. Charging can be performed by converting AC power into DC power through a converter such as an ACDC converter. The electric-powered vehicle may use a power line that connects the vehicle and the charging device 8021 using PLC (Power Line Communication) technology as a communication line.

Furthermore, although not illustrated, a power receiving device can be incorporated in the vehicle, and the vehicle can be charged by being supplied with power from an above-ground power transmitting device in a contactless manner. In the case of this contactless power feeding system, by incorporating a power transmitting device in a road or an exterior wall, charging can also be performed while the vehicle is driven without limitation on the period while the vehicle is stopped. In addition, this contactless power feeding system may be utilized to transmit and receive power between vehicles. Furthermore, a solar cell may be provided in the exterior of the vehicle to charge the secondary battery while the vehicle is stopped or while the vehicle is driven. For supply of power in such a contactless manner, an electromagnetic induction method or a magnetic resonance method can be used.

In addition, FIG. 3(C) is an example of a motorcycle using the charge state estimation device of a secondary battery of one embodiment of the present invention. A scooter 8600 illustrated in FIG. 3(C) includes a secondary battery 8602, side mirrors 8601, and direction indicators 8603. The secondary battery 8602 can supply electricity to the direction indicators 8603.

In the scooter 8600 illustrated in FIG. 3(C), the secondary battery 8602 can be stored in an under-seat storage 8604. The secondary battery 8602 can be stored in the under-seat storage 8604 even when the under-seat storage 8604 is small.

An embodiment described below in this specification includes use of a dedicated computer or a general-purpose computer including a variety of kinds of computer hardware or software. A computer-readable recording medium can be used and mounted on the embodiment described below in this specification. As the recording medium, a RAM, a ROM, an optical disk, a magnetic disk, and other appropriate storage media that can be accessed by a computer may be included. Algorithms, components, flows, programs, and the like presented as examples in an embodiment described below in this specification can be implemented in software or implemented in a combination of hardware and software.

This embodiment can be combined with the description of the other embodiments as appropriate.

### Embodiment 2

Sudden noise such as a micro-short circuit can be detected according to Embodiment 1. If a value calculated by the above Formula 8 exceeds a threshold value, the noise thereof can be specified as a micro-short circuit; therefore, other noise is classified and the noise and a driving pattern are linked to each other to perform machine learning.

If a noise can be linked like a micro-short circuit, it can be understood that the noise is caused by a secondary battery. As for other noise, data is collected from a motor, an inverter, a converter, a wireless module or the like, analyzed and learned in order to understand what kind of a noise the noise is whereby the noise thereof is classified. If an abnormality is detected therein, not only the abnormality of the secondary battery but also failure, a sign leading to failure, or the like of the motor, the inverter, the converter, the wireless module or the like can be detected.

In the case where a signal to cancel noise is formed, cancelation can be performed by an overlapping by a signal with the opposite phase; however, a charge rate (SOC) or the like can be calculated by arithmetic processing by a numeral value with which cancelation is regarded to have been performed even when the cancelation has not been performed. When noise is canceled, noise is removed from a signal; hence, malfunction does not occur in other circuits or the like.

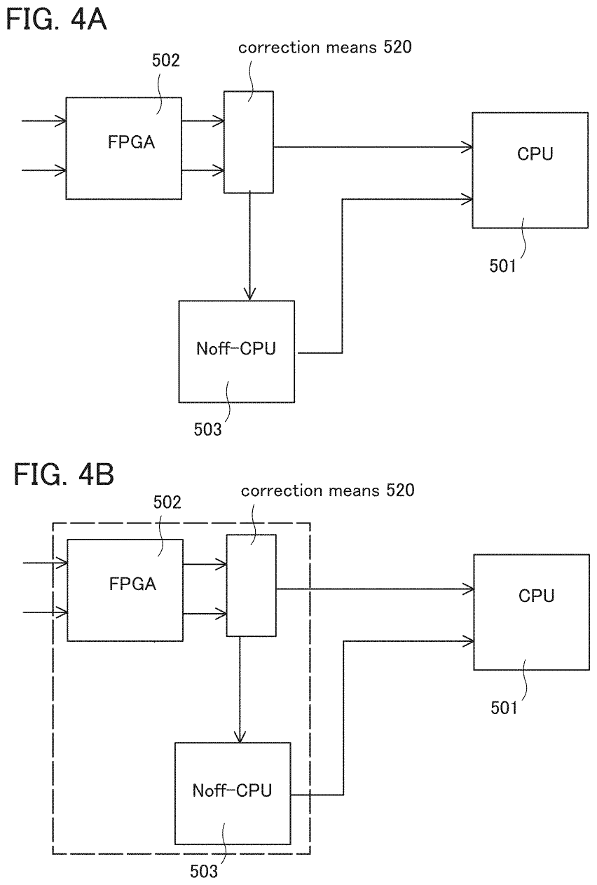

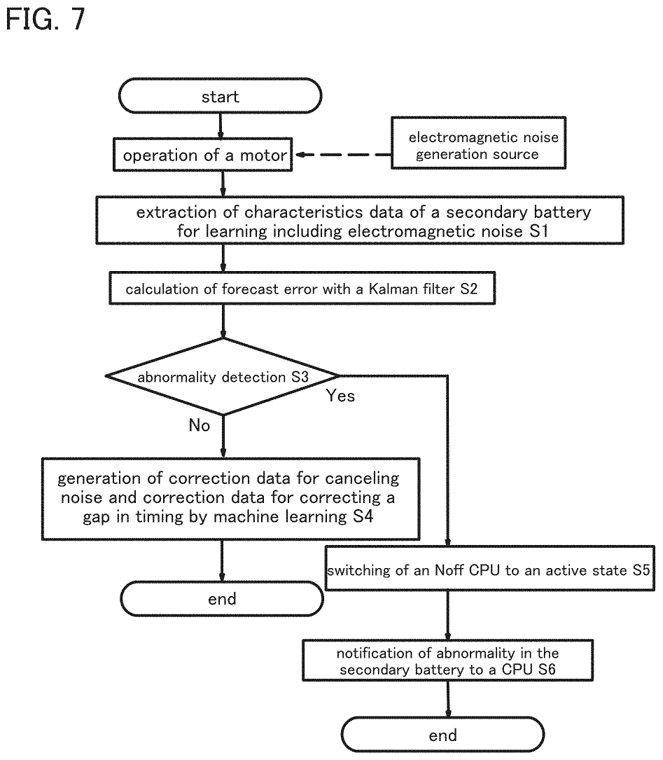

FIG. 4 illustrates an example of a management system that can estimate SOC of a secondary battery and also perform abnormality detection in FIG. 4. FIG. 7 illustrates a flow diagram of performing abnormality detection. As illustrated in FIG. 7, by operating a motor, electromagnetic noise is generated and characteristics data of a secondary battery including electromagnetic noise is extracted (S1). Forecast error is calculated with a Kalman filter (S2), and when an abnormality is detected (S3), an Noff-CPU (normally-off CPU) is switched to an active state (S5) and the abnormality is notified to a CPU (S6). When an abnormality is not detected, correction for canceling the noise and correction data for correcting a timing gap is generated by machine learning (S4). Note that the normally-off CPU is an integrated circuit including a normally-off transistor which is in a non-conduction state (also referred to as an off state) even when a gate voltage is 0 V. The normally-off transistor can be achieved by using an oxide semiconductor for a semiconductor layer.

FIG. 4(A) shows an example of a configuration diagram of the management system. An ECU for controlling an electric vehicle includes a microcomputer, and the microcomputer includes a CPU (Central Processing Unit) 501 and manages the entire electric vehicle. In this embodiment, an example where the CPU 501 is used is illustrated; however, one embodiment is not limited thereto if necessary calculation can be performed and a GPU (Graphics Processing Unit) or an APU (Accelerated Processing Unit) can be used. Note that an APU refers to a chip integrating a CPU and a GPU into one.

An FPGA 502 includes an element structure where SOC, internal resistance, or the like is output using an element that detects an actual voltage (observation voltage) of a secondary battery or an actual current (observation current) of a secondary battery, and information thereof is provided to the CPU 501. The number of bits that the CPU 501 can process in an internal arithmetic circuit or in a data bus can be 8, 16, 32, or 64, for example.

An Noff-CPU 503 in FIG. 4(A) has a circuit structure where the Noff-CPU 503 is in standby being in a non-active state and enters an active state for the first time when an abnormality is detected, and the abnormality is notified to the CPU 501. The Noff-CPU 503 includes a transistor including an oxide semiconductor partially therein, and the transistor is normally-off. A normally-off transistor has electrical characteristics where a threshold voltage becomes positive (also referred to as normally-off characteristics). The number of bits that the Noff-CPU 503 can process in an internal arithmetic circuit or in a data bus can be 8, 16, 32, or 64, for example.

A correction means 520 sequentially takes in a forecast error voltage obtained in the FPGA 502, constantly captures a time-series forecast error voltage at a certain length, and adds a signal for canceling unnecessary electromagnetic noise obtained by machine learning (a signal with the opposite phase from the unnecessary electromagnetic noise), whereby a forecast error signal with unnecessary electromagnetic noise removed therefrom is calculated, and SOC, a parameter of internal resistance, or the like is corrected based on the forecast error voltage.

In the case where the forecast error signal exceeds a preset threshold value, it is determined that there is an abnormality; whereby, the Noff-CPU 503 enters an active state and the abnormality is notified to the CPU 501.

For the learning means, first, a feature value is extracted from learning data. A relative change in amount that changes in accordance with time is extracted as a feature value, and a neural network is made to learn based on the extracted feature value. For the learning means, the neural network can be made to learn based on learning patters that are different between each time division. A coupling weight coefficient applied to the neural network can be updated according to a leaning result based on the leaning data.

A correction means where a large amount of leaning data of noise having a causal relationship with a driving pattern is collected in advance and analyzed results thereof is used for linking can be implemented. For the correction in the correction means 520, treatment where noise is canceled using a signal with the opposite phase from the noise is performed. Not only a neural network but also a linear model or a Kernel model can be used.

Estimation treatment of SOC in which calculation in the CPU 501 based on data on which two different corrections were performed as above is performed and a charge rate is calculated; whereby, value with high accuracy can be obtained.

Since a micro-short circuit with abnormality detection of low frequency rarely occurs, a normally-off CPU that is normally not in operation, in other words, the circuit thereof is stooped for reducing energy consumption is preferable.

On the other hand, the correction means 520 can perform charge state estimation with high accuracy real time or semi-real time, since measurement is performed constantly and noise cancelation is performed. The term real time used in this specification refers to being substantially simultaneous and includes delay in signal processing. Semi-real time refers to a wider application range than real time and refers to, for example, a delay of longer than or equal to 10 seconds and shorter than or equal to 3600 seconds.

Without particular limitation to the example in FIG. 4(A), a structure illustrated in FIG. 4(B) may be employed, for example. FIG. 4(B) is an example in which the Noff-CPU 503 and the FPGA 502 are on the same chip. With the Noff-CPU 503 and the FPGA 502 being on the same chip, space reduction and high integration can be achieved. The FPGA 502 and the correction means 520 can be on the same chip.

### Embodiment 3

In this embodiment, a structure example of a neural network NN used for the neural network processing at the time of the estimation treatment of SOC where calculation is performed in the CPU 501 shown in FIG. 4 in Embodiment 2 is described.

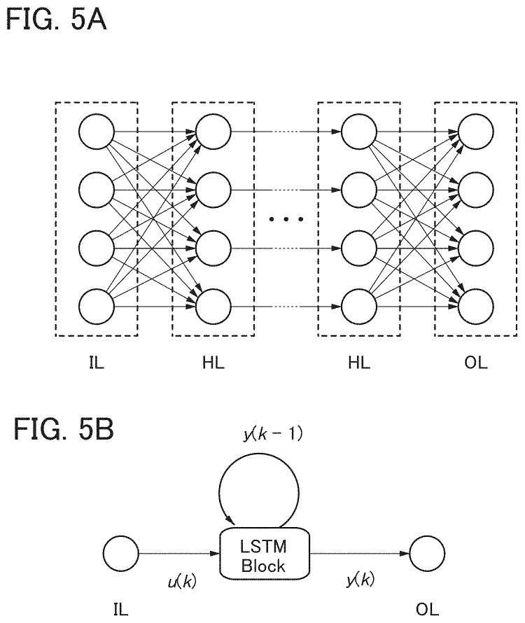

FIG. 5(A) illustrates an example of a neural network of one embodiment of the present invention. The neural network NN illustrated in FIG. 5(A) includes an input layer IL, an output layer OL, and hidden layers (middle layer) HL. The neural network NN can be formed of a neural network including the plurality of hidden layers HL, that is, a deep neural network. Learning in a deep neural network is referred to as deep learning in some cases.

The output layer OL, the input layer IL, and the hidden layers HL illustrated in FIG. 5(A) each include a plurality of neuron circuits, and the neuron circuits provided in the different layers are connected to each other through a synapse circuit.

A function of analyzing a state of a secondary battery, a function of analyzing noise, a function of generating a signal for canceling noise, or the like is added to the neural network NN through learning. When a measured parameter of a secondary battery is input to the neural network NN, arithmetic processing is performed in each layer. The arithmetic processing in each layer is executed through, for example, the product-sum operation of the output from a neuron circuit in the previous layer and a weight coefficient. Note that the connection between layers may be a full connection where all of the neuron circuits are connected or may be a partial connection where some of the neuron circuits are connected.

For example, a recurrent neural network with an LSTM (Long Short-Term Memory) structure illustrated in FIG. 5(B) is used. In a recurrent neural network with an LSTM structure, the recognition rate of sequential data with a longer sequence can be increased compared to other structures.

In an LSTM, a hidden layer (interlayer) HL is a block called an LSTMBock including a memory and three gates. The three gates are an input gate, a forget gate, and an output gate.

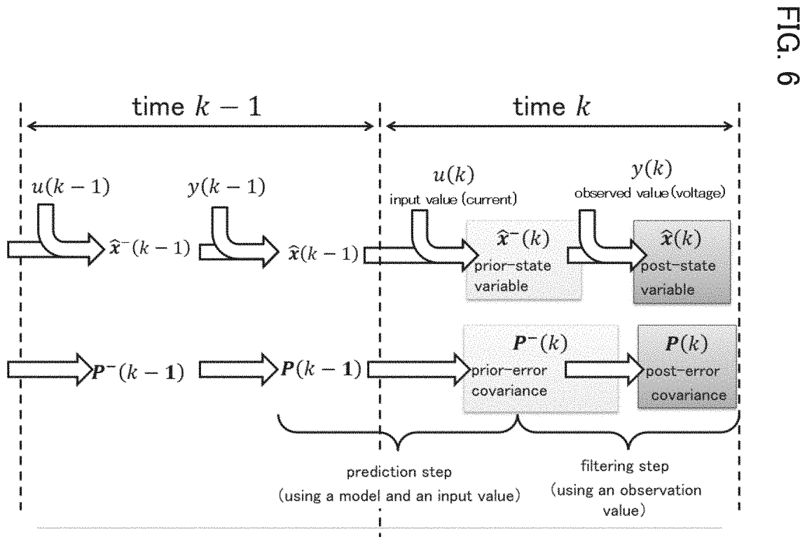

FIG. 6 illustrates a conceptual diagram of an operation step during time (k−1) and time k. In a Kalman filter, a prediction step and a filtering step are performed each time one time passes.

In the prediction step, a prior error covariance (P−(k)) is determined using a post error covariance (P(k−1)) in a prior step. Note that in the case where a prior state variable is determined, an input value of a system (in this embodiment it is a current value u(k) of a battery) is also used to determine a prior-state variable.

In the filtering step a post-error covariance is determined using a prior-error covariance, and a post state variable is determined using a prior state variable and an observation value (in this embodiment it is a voltage y(k) of a battery). Note that in an LSTM, y(k) is an output value and is output using an output value y(k−1) of a prior time k−1.

The recurrent neural network with an LSTM structure can be executed using a management system illustrated in FIG. 4(A) and FIG. 4(B).

Energy consumption can be reduced by using a transistor using an oxide semiconductor as a memory unit of the FPGA 502, or a memory unit of the CPU 501, illustrated in FIG. 4. In the case where a product-sum operation or the like in a neural network is performed, it is useful since a large amount of arithmetic processing is performed in a state where data is retained in the memory unit.

This embodiment can be freely combined with Embodiment 1 or Embodiment 2.

### Embodiment 4

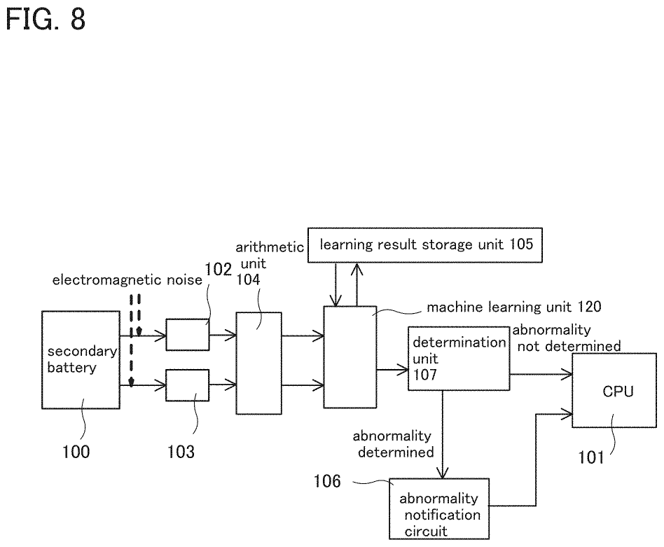

FIG. 8 illustrates an example of a block diagram of an abnormality detection device of a secondary battery 100. The abnormality detection device of the secondary battery 100 illustrated in FIG. 8 can be used for vehicles such as an electric vehicle or a hybrid electric vehicle. As illustrated in FIG. 8, the abnormality detection device of the secondary battery 100 includes at least a current monitor IC 102 which is the current obtaining unit, a voltage monitor IC 103 which is the voltage obtaining unit, an arithmetic unit 104, a machine learning unit 120, a learning result storage unit 105, and a determination unit 107.

The arithmetic unit 104, the learning result storage unit 105, the machine learning unit 120, and the determination unit 107 can collectively serve as a learning unit, and the learning unit includes an FPGA, a microcontroller, and the like.

A lithium-ion secondary battery is used as the secondary battery 100. In the case of using a lithium-ion secondary battery in a vehicle, a plurality of lithium-ion secondary batteries is used; however, here, a plurality of secondary batteries is illustrated as one secondary battery for simplification. In a lithium-ion secondary battery, deterioration is promoted if charging or discharging is performed too much. Thus, in the lithium-ion secondary battery, charge and discharge are managed by a protection circuit, a control circuit, or the like so that the charge rate stays within a certain range (for example, higher than or equal to 20% and lower than or equal to 80%).

The current monitor IC 102 inputs a detected current value of the secondary battery 100 into the arithmetic unit 104. The voltage monitor IC 103 inputs a detected voltage value of the secondary battery 100 into the arithmetic unit 104.

The arithmetic unit 104 includes an equivalent circuit model of the secondary battery 100 and a Kalman filter. The arithmetic unit 104 can estimate a parameter value based on the input current value and voltage value, and calculate forecast error based on the estimated parameter value.

The machine learning unit 120, with forecast error and a driving pattern as an input, generates correction data for the forecast error and forms a correction model by linking the correction data and the driving pattern so as to cancel the noise linked to the driving pattern. A driving pattern of a vehicle and electromagnetic noise can be linked to each other in many cases, and the noise can be determined to be electromagnetic noise if the noise is linked to a driving pattern of a vehicle. A change not linked to a driving pattern of a vehicle can be attributed to a secondary battery.

The learning result storage unit 105 stores result of the machine learning unit. A large amount of leaning data of noise having a causal relationship with a driving pattern is collected and analyzed results thereof are stored.

The determination unit 107 determines whether forecast error corrected using correction data is normal or abnormal by comparing the forecast error with a threshold value.

The determined result is notified to an upper control portion of a vehicle, for example, a CPU 101. The CPU 101 prompts a user (driver) or the like to take response measures when notified of an abnormality.

In the case where the determination unit 107 is normal, the CPU 101 does not necessarily need to be notified, and the time during which it was determined to be normal can be recorded. In the case of a secondary battery with high reliability, abnormality rarely occurs in the secondary battery; thus, it is desirable that the determination unit 107 be always kept in a non-operative state and power consumption be set extremely low even when the determination unit 107 is in a non-operative state for along period of time. Thus, an abnormality notification circuit 106 electrically connected to the determination unit 107 may be provided and an Noff-CPU may be used. The abnormality notification circuit 106 can have a structure where a user (driver) or the like is prompt to take response measures when an occurrence of an abnormality is determined.

The Noff-CPU includes a transistor and an oxide semiconductor is included in part of the transistor; furthermore, the transistor is normally-off. A normally-off transistor has electrical characteristics where a threshold voltage becomes positive (also referred to as normally-off characteristics). The number of bits that the Noff-CPU can process in an internal arithmetic circuit or in a data bus can be 8, 16, 32, or 64, for example. The abnormality notification circuit 106 in FIG. 8 has a circuit structure where the abnormality notification circuit 106 is in standby being in a non-active state and shifts to an active state for the first time when an abnormality is detected, and notifies the CPU 101.

By using an abnormality detection device illustrated in FIG. 8, a sudden abnormality such as a micro-short circuit can be detected. As for other sudden abnormalities, linking is performed based on data from a motor, an inverter, a converter, a wireless module, or the like to understand what kind of a noise the noise is, and analysis and learning is performed whereby the noise is classified. If an abnormality is detected therein, not only the abnormality of the secondary battery but also failure, a sign of failure, or the like of the motor, the inverter, the converter, the wireless module or the like can be detected.

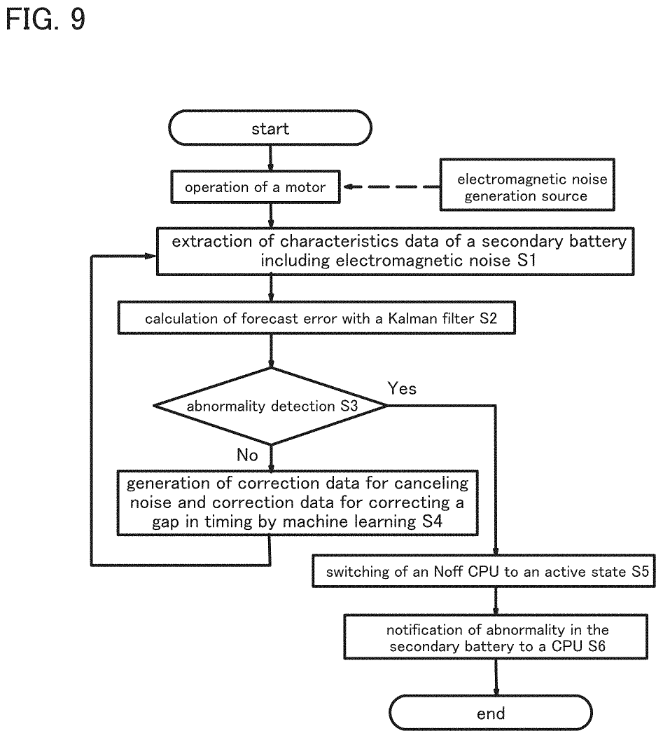

FIG. 9 illustrates an example of a flow of performing abnormality detection.

As illustrated in FIG. 9, by operating a motor, electromagnetic noise is generated and characteristics data of a secondary battery including electromagnetic noise is extracted (S1). Forecast error is calculated with a Kalman filter (S2), and when an abnormality is detected (S3), the Noff-CPU is switched to an active state (S5) and the abnormality is notified to the CPU (S6). When an abnormality is not detected, correction for canceling the noise with machine learning and correction data for correcting a timing gap is generated (S4). When an abnormality is not detected, steps S1, S2, S3, and S4 will be repeated in this order and real-time checking can be performed. Note that abnormality detection can be performed intermittently with a certain interval, without being particularly limited to real time.

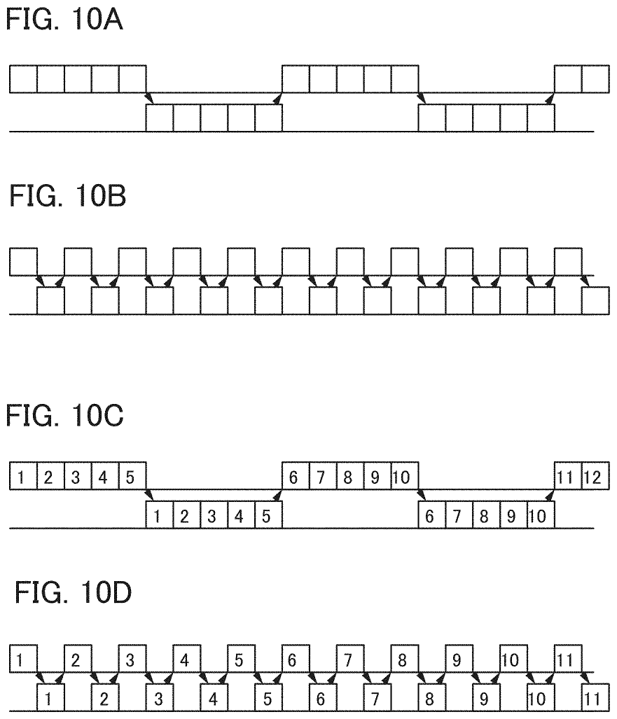

FIG. 10(A) illustrates a conceptual diagram in which a gap in timing due to asynchronicity is corrected by performing the prior-estimate prediction step and the post-estimate step are collectively performed to some extent. In FIG. 10(A), the horizontal axis represents time and the upper side is the prior-estimate prediction step and the lower side is the post-estimate step. By adopting the method illustrated in FIG. 10(A) the gap in timing can also be learned.

In the prior-estimate prediction step, an estimation algorithm and an input value are used, and in the post-estimate step (also referred to as a filtering step), an observation value is used.

As a comparative example, FIG. 10(B) illustrates a conceptual diagram where the Kalman filter is used successively.

In an assembled battery, each secondary battery is not successively filtered, and the prior-estimate prediction step and the post-estimate step can collectively be performed to some extent, and an example thereof is illustrated in FIG. 10(C). In FIG. 10(C), the horizontal axis represents time and the upper side is the prior-estimate prediction step and the lower side is the post-estimate step. In FIG. 10(C), five secondary batteries are combined into one whereby the prior-estimate prediction step is performed.

As a comparative example, FIG. 10(D) illustrates a conceptual diagram where the Kalman filter is used successively.

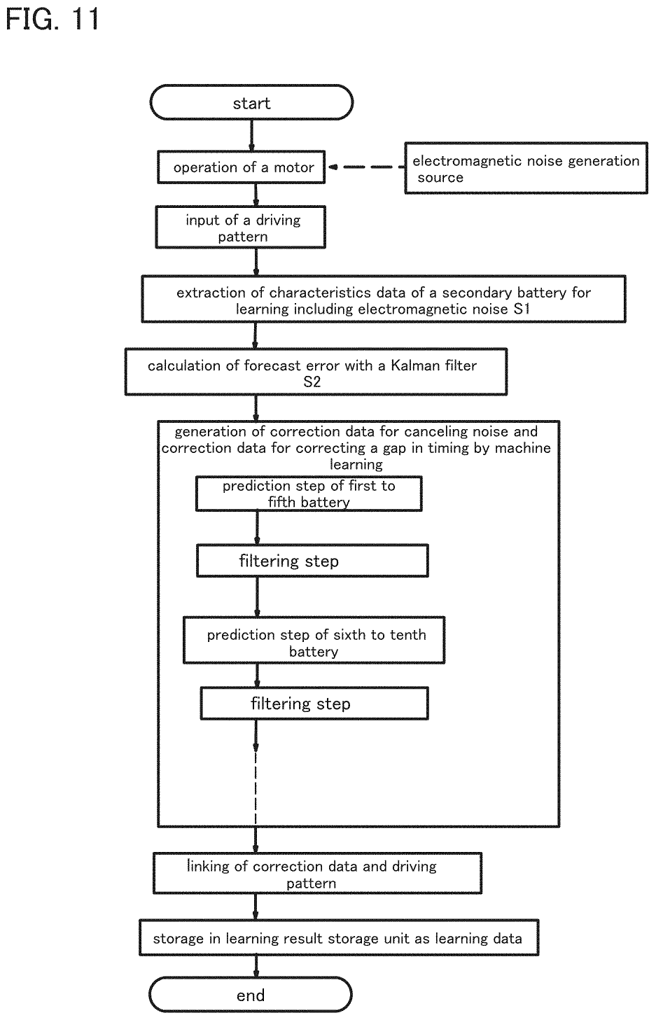

FIG. 11 illustrates an example of a learning flow where learning of an assembled battery including 10 or more batteries is performed in the order shown in FIG. 10(C).

As illustrated in FIG. 11, by operating a motor, electromagnetic noise is generated and characteristics data of a secondary battery including electromagnetic noise is extracted (S1). Then, forecast error is calculated using a Kalman filter (S2), and correction for canceling noise by machine learning and correction data for correcting a gap in timing are generated.

When generating this correction data, the prior-estimate prediction step for a first to a fifth battery of the assembled battery is collectively performed and then, the post-estimate step for the first to the fifth battery of the assembled battery is collectively performed. Then the prior-estimate prediction step for a sixth to a tenth battery of the assembled battery is collectively performed and then, the post-estimate step for the sixth to the tenth battery of the assembled battery is collectively performed. After that, similar steps can be performed on five batteries among the remaining batteries of the assembled battery at a time.

Then, a driving pattern and the obtained correction data are linked to each other, and the data thereof is stored in the learning result storage unit as learning data. By performing learning using the learning flow illustrated in FIG. 11 in advance, abnormality detection can be performed with high accuracy.

In the case where the amount of learning data becomes large due to the number of assembled batteries being high or the number of driving patterns being high, the data can be stored in a data server or the like that can perform communication outside of a vehicle. In that case, abnormality detection will be performed by data communication being performed between the learning result storage unit installed outside of a vehicle and the machine learning unit installed inside of the vehicle.

### Embodiment 5

The abnormality detection device of a secondary battery of one embodiment of the present invention can be applied to a device including a secondary battery and a wireless nodule, not being limited to a vehicle.

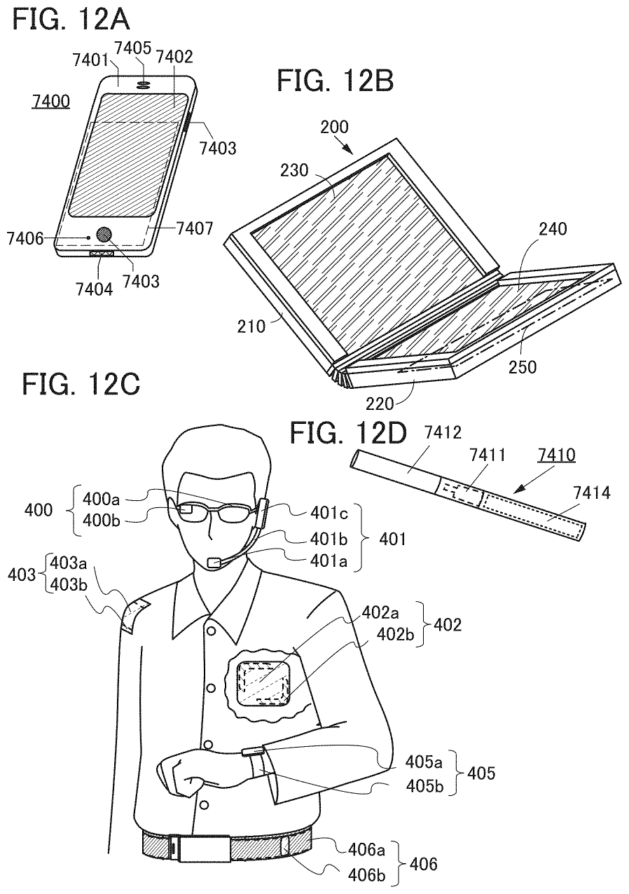

FIG. 12(A) illustrates an example of a mobile phone. A mobile phone 7400 includes operation buttons 7403, an external connection port 7404, a speaker 7405, a microphone 7406, and the like in addition to a display portion 7402 incorporated in a housing 7401. Note that the mobile phone 7400 includes a secondary battery 7407 and an abnormality detection device of the secondary battery 7407. Even if a wireless module for sending and receiving data and the secondary battery 7407 are positioned close to each other, abnormality detection can be perfumed while separating noise by the abnormality detection device described in the above embodiment.

FIG. 12(B) is a projection diagram showing an example of an external view of an information processing device 200. The information processing device 200 illustrated in this embodiment includes an arithmetic device 210, an input/output device 220, a display portion 230 and 240, a secondary battery 250, and an abnormality detection device.

The information processing device 200 includes a communication portion that can potentially be a noise source, and a wireless module has a function of supplying information to a network and obtaining information from a network. Information distributed in a specific area can be received using the communication portion and image data can be generated based on the received information. The information processing device 200 can function as a personal computer when a screen in which a keyboard is displayed is set as a touch input panel, either in the display portion 230 or 240.

The abnormality detection device of a secondary battery of one embodiment of the present invention can be provided in a wearable device illustrated in FIG. 12(C).

For example, the abnormality detection device can be provided in a glasses-type device 400 illustrated in FIG. 12(C). The glasses-type device 400 includes a frame 400a and a display portion 400b and a wireless module. Since abnormality detection can be performed without being affected by noise even when a secondary battery, the abnormality detection device, and the wireless module are positioned close to each other in the temple portion of the frame 400a with curvature, the glass-type device 400 that can detect abnormality occurrence of a secondary battery and is safe can be achieved.

A secondary battery, the abnormality detection device, and a wireless module can be provided in a headset-type device 401. The headset-type device 401 includes at least a microphone portion 401a, a flexible pipe 401b, and an earphone portion 401c. The secondary battery, the abnormality detection device, and the wireless module can be provided in the flexible pipe 401b or the earphone portion 401c.

The abnormality detection device can be provided in a device 402 that can be directly attached to a human body. A secondary battery 402b and the abnormality detection device of a secondary battery can be provided in a thin housing 402a of the device 402.

The abnormality detection device can be provided in a device 403 that can be attached to clothing. A secondary battery 403b and the abnormality detection device of a secondary battery can be provided in a thin housing 403a of the device 403.

Furthermore, the abnormality detection device can be provided in an watch-type device 405. The watch-type device 405 includes a display portion 405a and a belt portion 405b, and a secondary battery and the abnormality detection device of a secondary battery can be provided in the display portion 405a or the belt portion 405b.

The display portion 405a can display various kinds of information such as reception information of an e-mail or an incoming call in addition to time.

Since the watch-type device 405 is a type of wearable device that is directly wrapped around an arm, a sensor that measures pulse, blood pressure, or the like of a user can be provided therein. Data on the exercise quantity and health of the user can be stored to be used for health maintenance.

A secondary battery and the abnormality detection device of a secondary battery can be provided in a belt-type device 406. The belt-type device 406 includes a belt portion 406a and a wireless power-feeding/power-receiving portion 406b, and a secondary battery, the abnormality detection device, and a wireless module can be provided in the belt-portion 406a.

By using the secondary battery and the abnormality detection device of a secondary battery of one embodiment of the present invention as a secondary battery of a daily electronic product, a light and safe product can be provided. Examples of the daily electronic product include an electric toothbrush, an electric shaver, electric beauty equipment, and the like. As power storage devices of these products, small and lightweight secondary batteries with stick-like shapes and high capacity are desired in consideration of handling ease for users. FIG. 12(D) is a perspective diagram of a device called a cigarette smoking device (electronic cigarette). In FIG. 12(D), an electronic cigarette 7410 is composed of an atomizer 7411 including a heating element, a secondary battery 7414 that supplies power to the atomizer, and a cartridge 7412 including a liquid supply bottle, a sensor, and the like. To improve safety, the abnormality detection device of a secondary battery may be electrically connected to the secondary battery 7414. The secondary battery 7414 illustrated in FIG. 12(D) includes an external terminal for connection to a charger. When the secondary battery 7414 is held, the secondary battery 7414 becomes a tip portion; thus, it is desirable that the secondary battery 7414 have a short total length and be lightweight. Since an occurrence of abnormality in the secondary battery and noise by the atomizer 7411 can be separated, the abnormality detection device of one embodiment of the present invention can provide the electronic cigarette 7410 that is safe.

Note that this embodiment can be combined as appropriate with any of the other embodiments.

### REFERENCE NUMERALS

100: secondary battery, 101: CPU, 102: current monitor IC, 103: voltage monitor IC, 104: arithmetic unit, 105: learning result storage unit, 106: abnormality notification circuit, 107: determination unit, 120: machine learning unit, 200: information processing device, 210: arithmetic device, 220: input/output device, 230: display portion, 240: display portion, 250: secondary battery, 300: abnormality-monitoring unit, 301: battery, 302: battery controller, 303: motor controller, 304: motor, 305: gear, 306: DCDC circuit, 307: electric power steering, 308: heater, 309: defogger, 310: DCDC circuit, 311: battery, 312: inverter, 314: power window, 315: lamps, 316: tiers, 320: correction means, 400: glass-type device, 400a: frame, 400b: display portion, 401: headset-type device, 401a: microphone portion, 401b: flexible pipe, 401c: earphone portion, 402: device, 402a: housing, 402b: secondary battery, 403: device, 403a: housing, 403b: secondary battery, 405: watch-type device, 405a: display portion, 405b: belt portion, 406: belt-type device, 406a: belt portion, 406b: wireless power-feeding/power-receiving portion, 501: CPU, 502: FPGA, 503: Noff-CPU, 520: correction means, 600: secondary battery, 601: positive electrode cap, 602: battery can, 603: positive electrode terminal, 604: positive electrode, 605: separator, 606: negative electrode, 607: negative electrode terminal, 608: insulating plate, 609: insulating plate, 611: PTC element, 612: safety valve mechanism, 613: conductive plate, 614: conductive plate, 1400: secondary battery, 1402: positive electrode, 1404: negative electrode, 7400: mobile phone, 7401: housing, 7402: display portion, 7403: operation button, 7404: external connection port, 7405: speaker, 7406: microphone, 7407: secondary battery, 7410: electronic cigarette, 7411: atomizer, 7412: cartridge, 7414: secondary battery, 8021: charging device, 8022: cable, 8024: secondary battery, 8400: automobile, 8401: head light, 8406: electric motor, 8500: automobile, 8600: scooter, 8601: side mirror, 8602: secondary battery, 8603: direction indicator, 8604: under-seat storage

1. An abnormality detection device of a secondary battery comprising:
a voltage obtaining unit which measures a voltage value of a secondary battery;
a current obtaining unit which measures a current value of a secondary battery;
an arithmetic unit which calculates forecast error by calculation using a regression model with the voltage value and the current value as an input;
a machine learning unit which, with the forecast error and a driving pattern as an input, generates correction data for forecast error and forms a correction model by linking the correction data and the driving pattern so as to cancel noise linked to the driving pattern;
a learning result storage unit which stores a result of the machine learning unit; and
a determination unit which determines whether a forecast error corrected using the correction data is normal or abnormal.

2. The abnormality detection device of a secondary battery according to claim 1, further comprising an abnormality notification circuit which operates and notifies a user of an abnormality only when the corrected forecast error is determined to be abnormal.

3. The abnormality detection device of a secondary battery according to claim 1, wherein the regression model is a Kalman filter on the basis of a state equation.

4. The abnormality detection device of a secondary battery according to claim 1, wherein in the regression model, a plurality of filtering steps is performed successively after a plurality of prediction steps is performed successively.

5. The abnormality detection device of a secondary battery according to claim 1, wherein the machine learning unit comprises a neural network.

6. The abnormality detection device of a secondary battery according to claim 2, wherein the abnormality notification circuit comprises at least a transistor with a metal oxide layer as a channel.

7. The abnormality detection device of a secondary battery according to claim 1, wherein the secondary battery is a lithium-ion secondary battery.

8. The abnormality detection device of a secondary battery according to claim 1, wherein the secondary battery is an all-solid-state battery.

9. The abnormality detection device of a secondary battery according to claim 3, wherein in the regression model, a plurality of filtering steps is performed successively after a plurality of prediction steps is performed successively.

10. The abnormality detection device of a secondary battery according to claim 9, wherein the machine learning unit comprises a neural network.
